(19) United States
(12) Patent Application Publication
(10) Pub. No.: US 2019/0378775 A1
(43) Pub. Date: Dec. 12, 2019

(54) SEMICONDUCTOR PACKAGE

(71) Applicant: SAMSUNG ELECTRONICS CO., LTD., Suwon-si (KR)

(72) Inventors: Yong Koon LEE, Suwon-si (KR); Jin Su KIM, Suwon-si (KR)

(73) Assignee: SAMSUNG ELECTRONICS CO., LTD., Suwon-si (KR)

(21) Appl. No.: 16/169,656

(22) Filed: Oct. 24, 2018

(30) Foreign Application Priority Data
Jun. 11, 2018 (KR) 10-2018-0066598

(51) Int. Cl. H01L 23/31; H01L 23/538; H01L 25/16; H05K 3/28

(52) U.S. Cl. CPC H01L 23/3135; H01L 23/3121; H05K 3/284; H01L 23/5389; H01L 25/16; H01L 23/5384

(57) ABSTRACT

A semiconductor package may include a core member having first and second through-holes, a passive component disposed in the first through-hole of the core member, a semiconductor chip disposed in the second through-hole of the core member and having an active surface on which connection pads are disposed and an inactive surface opposing the active surface, a first encapsulant encapsulating at least a portion of the passive component and having a first thermal conductivity, a second encapsulant encapsulating at least a portion of the semiconductor chip and having a second thermal conductivity higher than the first thermal conductivity, and a connection member disposed on the active surface of the semiconductor chip and including a redistribution layer electrically connected to the connection pads of the semiconductor chip.

### CROSS-REFERENCE TO RELATED APPLICATION(S)

This application claims benefit of priority to Korean Patent Application No. 10-2018-0066598 filed on Jun. 11, 2018 in the Korean Intellectual Property Office, the disclosure of which is incorporated herein by reference in its entirety.

### TECHNICAL FIELD

The present disclosure relates to a semiconductor package including a semiconductor chip and a passive component.

### BACKGROUND

In the field of semiconductor packaging technology, there has been continuous demand for small-sized semiconductor chips in terms of a form of a semiconductor chip, and in terms of functions of a semiconductor chip, a technique of a system in package (SiP) requiring complexation and multifunctionality has been demanded. To achieve this, there has been increased interest in a technique of mounting a plurality of chips and components in a single package.

Particularly, in the case of a semiconductor package including a component in which a high frequency signal is used, such as a communications module or a network module, it has been necessary to develop a structure for implementing thermal radiation properties while preventing degradation of electrical properties.

### SUMMARY

An aspect of the present disclosure is to provide a semiconductor package including a semiconductor chip and a passive component and implementing improved thermal radiation properties.

Another aspect of the present disclosure is to provide a semiconductor package in which a semiconductor chip and a passive component are encapsulated by materials having different levels of thermal conductivity.

According to an aspect of the present disclosure, a semiconductor package includes a core member having first and second through-holes, a passive component disposed in the first through-hole of the core member, a semiconductor chip disposed in the second through-hole of the core member and having an active surface on which connection pads are disposed and an inactive surface opposing the active surface, a first encapsulant encapsulating at least a portion of the passive component and having a first thermal conductivity, a second encapsulant encapsulating at least a portion of the semiconductor chip and having a second thermal conductivity higher than the first thermal conductivity, and a connection member disposed on the active surface of the semiconductor chip and including a redistribution layer electrically connected to the connection pads of the semiconductor chip.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an exemplary embodiment of an electronic device system;

FIG. 2 is a perspective view illustrating an exemplary embodiment of an electronic device;

FIGS. 3A and 3B are cross-sectional views of states before and after packaging a fan-in semiconductor package;

FIG. 4 is a cross-sectional view illustrating a process of packaging a fan-in semiconductor package;

FIG. 5 is a cross-sectional view illustrating an exemplary embodiment in which a fan-in semiconductor package is mounted on an interposer substrate and ultimately mounted on a mainboard of an electronic device;

FIG. 6 is a cross-sectional view illustrating an exemplary embodiment in which a fan-in semiconductor package is embedded in an interposer substrate and ultimately mounted on a mainboard of an electronic device;

FIG. 7 is a cross-sectional view of a fan-out semiconductor package;

FIG. 8 is a cross-sectional view illustrating an exemplary embodiment in which a fan-out semiconductor package is mounted on a mainboard of an electronic device;

FIG. 9 is cross-sectional view illustrating an exemplary embodiment of a semiconductor package;

FIG. 10 is a cross-sectional view illustrating semiconductor package taken along line I-I′ in FIG. 9;

FIGS. 11A to 11I are views illustrating an exemplary embodiment of processes of manufacturing a semiconductor package in FIG. 9;

FIG. 12 is a cross-sectional view illustrating another exemplary embodiment of a semiconductor package;

FIG. 13 is a cross-sectional view illustrating another exemplary embodiment of a semiconductor package;

FIG. 14 is a cross-sectional view illustrating another exemplary embodiment of a semiconductor package;

FIG. 15 is a cross-sectional view illustrating another exemplary embodiment of a semiconductor package; and

FIG. 16 is a cross-sectional view illustrating another exemplary embodiment of a semiconductor package.

### DETAILED DESCRIPTION

Hereinafter, embodiments of the present disclosure will be described as follows with reference to the attached drawings. In the drawings, sizes and shapes of elements will be exaggerated or reduced for clear description.

Electronic Device

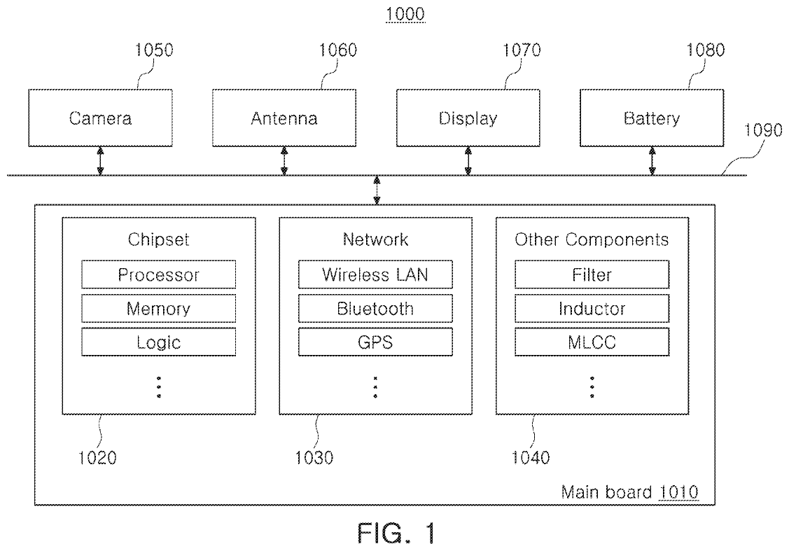

FIG. 1 is a block diagram illustrating an exemplary embodiment of electronic device system.

Referring to FIG. 1, an electronic device 100 may include a mainboard 1010. In the mainboard 1010, chip related components 1020, network related components 1030, and other components 1040 may be physically and/or electrically connected. These components may be combined with yet another component which will be described later and may form various signal lines 1090.

The chip related components 1020 may include a memory chip such as a volatile memory (e.g., a DRAM), a non-volatile memory (e.g., a ROM), a flash memory, or the like, an application processor chip such as a central processor (e.g., a CPU), a graphics processor (e.g., a GPU), a digital signal processor, a cryptographic processor, a microprocessor, a microcontroller, or the like, and a logic chip such as an analog-digital converter, an application specific IC (ASIC), or the like. However, the chip related components 1020 are not limited thereto, but may include other forms of chip related components. Also, the chip related components 1020 may be combined to one another.

The network related components 1030 may include wireless fidelity (Wi-Fi; Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the abovementioned protocols. However, the network related components 1030 are not limited thereto, and may also include a variety of other wireless or wired standards or protocols. Further, the network related components 1030 may be combined with one another along with the chip related components 1020.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor condenser (MLCC), or the like. However, other components 1040 are not limited thereto, but may also include passive components used for various other purposes, and the like. In addition, other components 1040 may be combined with one another along with the chip related components 1020 and/or the network related components 1030.

Depending on a type of the electronic device 1000, the electronic device 1000 may include yet other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive; not illustrated), a compact disk (CD) drive (not illustrated), a digital versatile disk (DVD) drive (not illustrated), or the like. However, the present disclosure is not limited thereto, but may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic devices processing data.

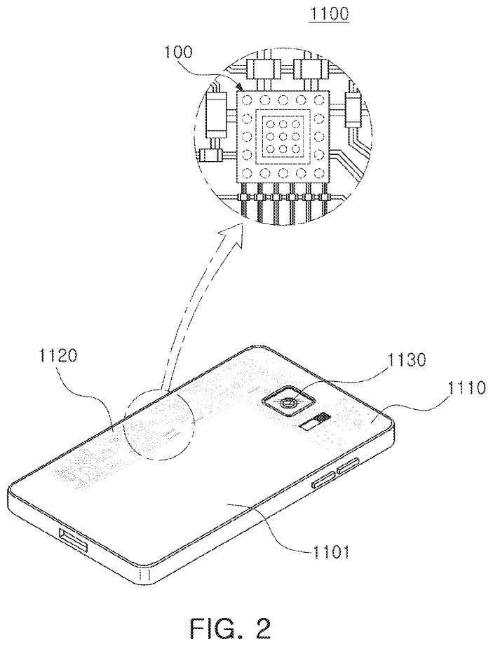

FIG. 2 is a perspective view illustrating an exemplary embodiment of an electronic device.

Referring to FIG. 2, a semiconductor package may be used for various purposes in various electronic devices as described above. For example, a motherboard 1110 may be provided in a body 1101 of a smartphone 1100, and various electronic components 1120 may be physically or electrically connected to the motherboard 1110. In addition, other components that may or may not be physically or electrically connected to the motherboard 1110, such as a camera 1130, may be provided in the body 1101. Some of the electronic components 1120 may be the chip related components, and a semiconductor package 100 may be an application processor among the components 1120, for example, but is not limited thereto. The electronic device is not necessarily limited to the smartphone 1100, but may be other electronic devices as described above.

Semiconductor Package

Generally, in a semiconductor chip, numerous fine electrical circuits are integrated, but such a semiconductor chip may not serve as a finished semiconductor product in itself, and a semiconductor chip may happen to be damaged due to external physical or chemical impacts. Accordingly, a semiconductor chip may not be used as it is, but may be packaged and used in an electronic device, and the like, in a packaged state.

A semiconductor packaging may be required because there may be a difference between a width of a circuit of a semiconductor chip a width of a circuit of a mainboard of an electronic device in terms of electrical connection. Specifically, in the case of a semiconductor chip, a size of connection pads of a semiconductor chip and an interval between the connection pads may be very fine, but in the case of a mainboard used in electronic devices, a size of component mounting pads of a mainboard and an interval between the component mounting pads are significantly larger than those of a semiconductor chip. Therefore, it may be difficult to directly mount the semiconductor chip on the mainboard, and packaging technology for buffering a difference in circuit width between the semiconductor chip and the mainboard may be necessary.

A semiconductor package manufactured by the packaging technology may be classified as a fan-in semiconductor package or a fan-out semiconductor package depending on a structure and a usage thereof.

In the description below, the fan-in semiconductor package and the fan-out semiconductor package will be described in greater detail with reference to the drawings.

Fan-in Semiconductor Package

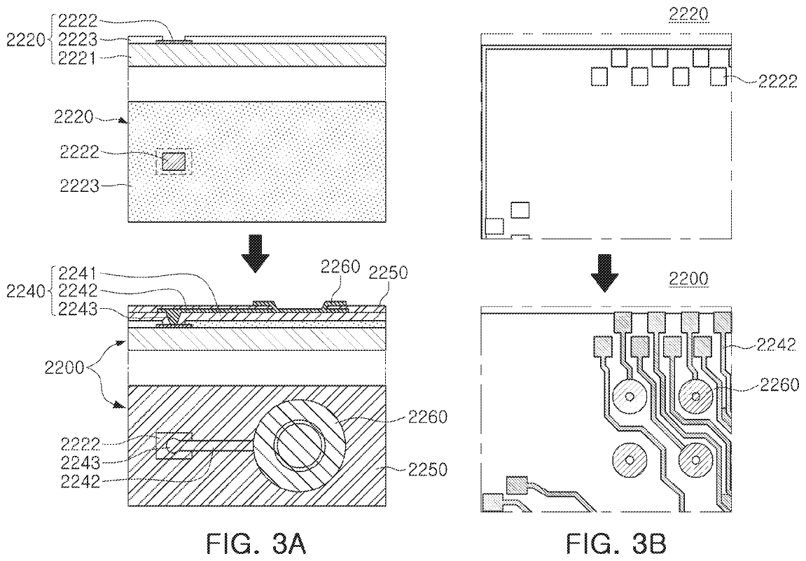

FIG. 3 is a cross-sectional view of states before and after packaging a fan-in semiconductor package.

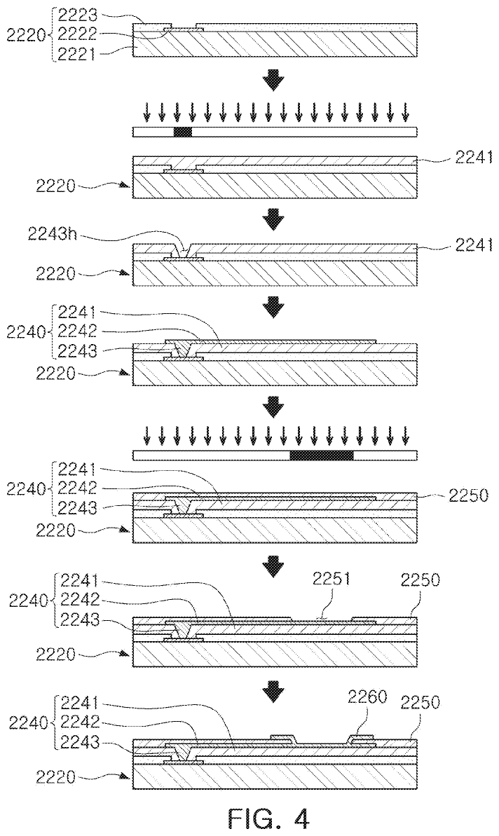

FIG. 4 is a cross-sectional view of a process of packaging a fan-in semiconductor package.

Referring to FIGS. 3 and 4, a semiconductor chip 2220 may be, for example, an integrated circuit (IC) in a bare state, including a body 2221 including silicon (Si), germanium (Ge), gallium arsenide (GaAs), and the like, connection pads 2222 formed on one surface of the body 2221 and including a conductive material such as aluminum (Al), and the like, and a passivation layer 2223 such as an oxide layer, a nitride layer, or the like, formed on one surface of the body 2221 and covering at least a portion of the connection pads 2222. In this case, since the connection pads 2222 may be significantly small, it may be difficult to mount the integrated circuit (IC) on an intermediate level printed circuit board (PCB) as well as on a mainboard of an electronic device, and the like.

Accordingly, to redistribute the connection pads 2222, a connection member 2240 may be formed in accordance with a size of the semiconductor chip 2220 on the semiconductor chip 2220. The connection member 2240 may be formed by forming an insulating layer 2241 on the semiconductor chip 2220 using an insulation material such as a photoimagable dielectric (PID) insulation material, forming a via hole 2243h opening the connection pads 2222, and forming wiring patterns 2242 and vias 2243. Then, a passivation layer 2250 protecting the connection member 2240 may be formed, an opening 2251 may be formed, and an underbump metal layer 2260, and the like, may be formed. Thus, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads of the semiconductor chip, such as input/output (I/O) terminals, are disposed inside the semiconductor chip, and may have excellent electrical properties and be produced at a relatively low cost. Therefore, many elements mounted in smartphones have been manufactured in a fan-in semiconductor package form. Specifically, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip of a compact size. In addition, due to the disadvantage as above, the fan-in semiconductor package may not be directly mounted and used on the mainboard of the electronic device. The reason is that even in the case in which a size of the I/O terminals of the semiconductor chip and an interval between the I/O terminals of the semiconductor chip are increased by a redistribution process, the size of the I/O terminals of the semiconductor chip and the interval between the I/O terminals may not be sufficient to directly mount the fan-in electronic component package on the mainboard of the electronic device.

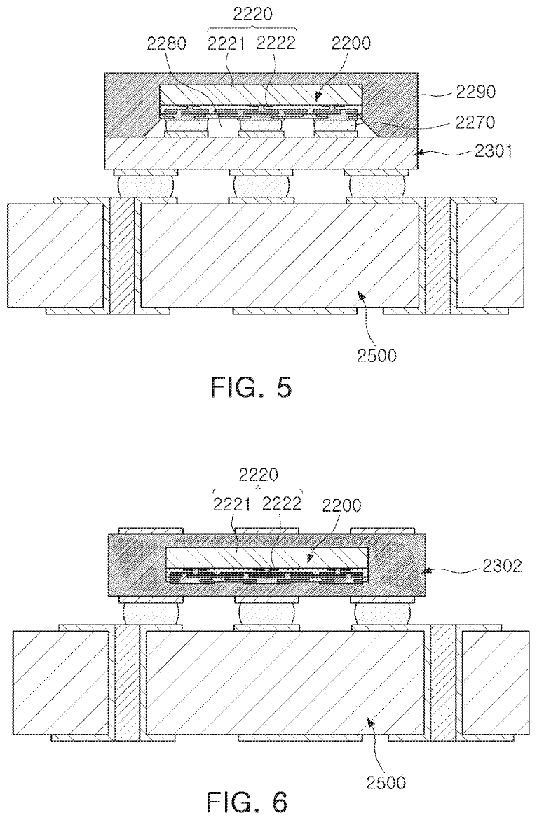

FIG. 5 is a cross-sectional view illustrating an exemplary embodiment in which a fan-in semiconductor package is mounted on an interposer substrate and ultimately mounted on a mainboard of an electronic device.

FIG. 6 is a cross-sectional view illustrating an exemplary embodiment in which a fan-in semiconductor package is embedded in an interposer substrate and ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through an interposer substrate 2301, and the fan-in semiconductor package 2200 may be ultimately mounted on a mainboard 2500 of an electronic device in a state in which the fan-in semiconductor package 2200 is mounted on the interposer substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate interposer substrate 2302, connection pads 2222, I/O terminals, of the semiconductor chip 2220 may be redistributed by the interposer substrate 2302 in a state in which the fan-in semiconductor package 2200 is embedded in the interposer substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Thus, the fan-in semiconductor package may be mounted on the separate interposer substrate and then mounted on the mainboard of the electronic device after going through a packaging process again, or may be mounted and used on the mainboard of the electronic device in a state in which it is embedded in the interposer substrate.

Fan-Out Semiconductor Package

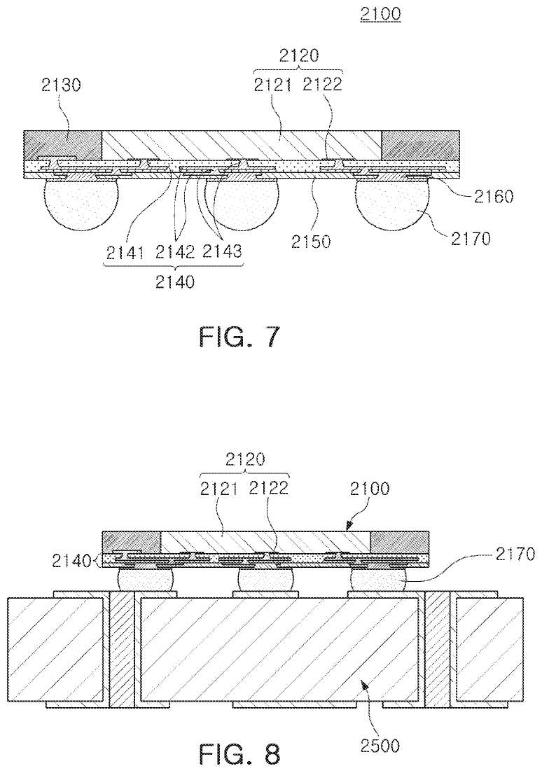

FIG. 7 is a cross-sectional view illustrating a fan-out semiconductor package.

Referring to FIG. 7, in a fan-out semiconductor package 2100, an outer portion of a semiconductor chip 2120 may be protected by an encapsulant 2130, for example, and connection pads 2122 of the semiconductor chip 2120 may be redistributed outwardly of the semiconductor chip 2120 by a connection member 2140. In this case, a passivation layer 2202 may further be formed on the connection member 2140, and an underbump metal layer 2160 may further be formed in openings of the passivation layer 2202. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As such, the fan-out semiconductor package may have a form in which I/O terminals are redistributed and disposed up to an external portion of the semiconductor chip through the connection member formed on the semiconductor chip. As described above, in the fan-in semiconductor package, as all I/O terminals of the semiconductor chip need to be disposed inside the semiconductor chip, a size of the semiconductor chip is decreased, and a size and a pitch of balls need to be decreased as well. Accordingly, it may not be possible to use a standardized ball layout in the fan-in semiconductor package. On the other hand, the fan-out semiconductor package has the form in which the I/O terminals of the semiconductor chip are redistributed and disposed up to an external portion of the semiconductor chip through the connection member formed on the semiconductor chip as described above. Thus, even in a case in which a size of the semiconductor chip is decreased, it may be possible to use a standardized ball layout in the fan-out semiconductor package as it is, and therefore, the fan-out semiconductor package may be mounted on the mainboard of the electronic device without using a separate interposer substrate, as described below.

FIG. 8 is a cross-sectional view illustrating an exemplary embodiment in which a fan-out semiconductor package is mounted on a mainboard of an electronic device.

Referring to FIG. 8, a fan-out semiconductor package 2100 may be mounted on a mainboard 2500 of an electronic device through solder balls 2170, and the like. In other words, as described above, as the fan-out semiconductor package 2100 includes the connection member 2140 capable of redistributing the connection pads 2122 up to a fan-out region that is beyond a size of the semiconductor chip 2120 on the semiconductor chip 2120, the standardized ball layout may be used in the fan-out semiconductor package 2100 as it is. As a result, the fan-out semiconductor package 2100 may be mounted on the mainboard 2500 of the electronic device without using a separate interposer substrate, or the like.

As described above, since the fan-out semiconductor package may be mounted on the mainboard of the electronic device without using a separate interposer substrate, the fan-out semiconductor package may be implemented to have a thickness lower than that of the fan-in semiconductor package using an interposer substrate. Therefore, the fan-out semiconductor package may be miniaturized and thinned. In addition, the fan-out electronic component package has excellent thermal properties and electrical properties, such that it is particularly appropriate for a mobile product. Further, the fan-out electronic component package may be implemented in a more compact form than that of a general package-on-package (POP) type using a printed circuit board (PCB), and may solve a problem caused by a warpage phenomenon.

Meanwhile, the fan-out semiconductor package refers to package technology for mounting the semiconductor chip on the mainboard of the electronic device, and the like, as described above, and protecting the semiconductor chip from external impacts. The fan-out semiconductor package is a concept different from that of a printed circuit board (PCB) such as an interposer substrate, or the like, having a scale, a purpose, and the like, different from those of the fan-out semiconductor package and having the fan-in semiconductor package embedded therein.

In the description below, a semiconductor package in which mounting areas of a semiconductor chip and passive components are reduced, an electronic path between a semiconductor chip and passive components is reduced, and thermal radiation properties and electrical properties are secured will be described with reference to the drawings.

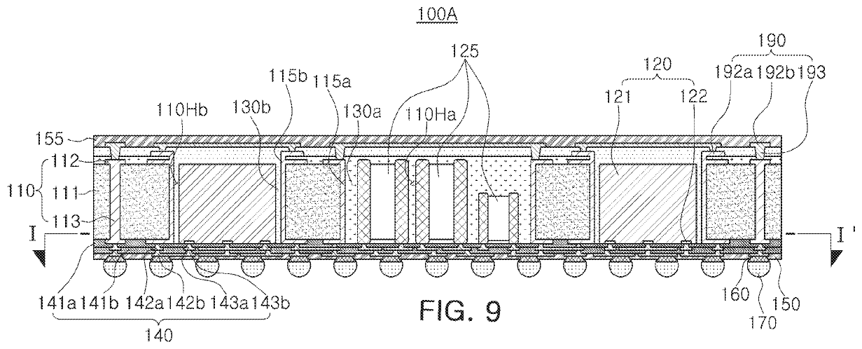

FIG. 9 is a cross-sectional view illustrating an exemplary embodiment of a semiconductor package.

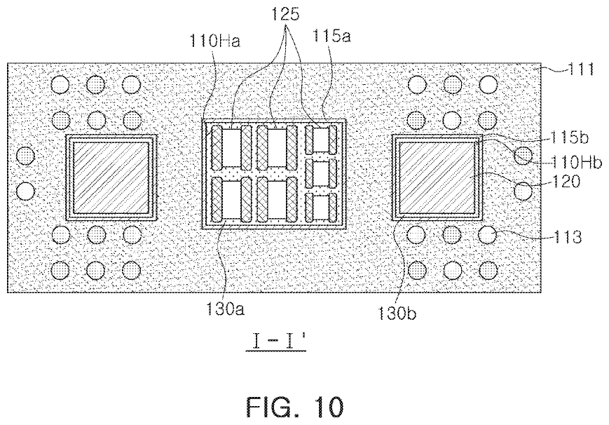

FIG. 10 is a cross-sectional view of semiconductor package taken along line I-I′ in FIG. 9.

Referring to the drawings, a semiconductor package 100A according to an exemplary embodiment may include a core member 110 having first and second through-holes 110Ha and 110Hb, first and second metal layers 115a and 115b disposed on internal walls of the first and second through-holes 110Ha and 110Hb, at least one passive component 125 disposed in the first through-hole 110Ha of the core member 110, a semiconductor chip 120 disposed in the second through-hole 110Hb of the core member 110 and having an active surface on which connection pads 122 are disposed and an inactive surface opposing the active surface, a first encapsulant 130a encapsulating at least a portion of the core member 110 and the passive components 125, a second encapsulant 130b encapsulating at least a portion of the core member 110 and the passive components 125, a connection member 140 disposed on the core member 110, the passive components 125 and the active surface of the semiconductor chip 120, a backside wiring structure 190 disposed on the core member 110, a backside passivation layer 155 disposed on the backside wiring structure 190, a passivation layer 150 disposed on the connection member 140, an underbump metal layer 160 disposed on openings of the passivation layer 150, and a electrical connection structure 170 disposed on the passivation layer 150 and connected to the underbump metal layer 160.

Recently, as sizes of displays for mobile apparatuses have been increased, it has been necessary to increase battery capacity. In accordance with an increase in battery capacity, an area occupied by a battery may also increase. To address the issue, it has been necessary to reduce a size of a printed circuit board (PCB), and along the reduced size of PCB, sizes of mounting areas of components have also been designed to be reduced as well. Accordingly, there have been increased interests in modularization. An example of a technique for mounting a plurality of components in the related art may be a chip on board (COB) technique. The COB is to mount individual passive elements and a semiconductor package on a printed circuit board using surface mount technology (SMT). The technique has an advantage in terms of costs, but because a wide mounting area is required to maintain a significantly reduced interval between components, electromagnetic interference (EMI) between components is high, and a distance between a semiconductor chip and passive components is great such that electric noise may increase.

However, in the semiconductor package 100A according to the exemplary embodiment, a plurality of passive components 125 and the semiconductor chip 120 may be disposed and modularized in a single package. Accordingly, a distance between components may be reduced, and a mounting area in a printed circuit substrate such as a mainboard may be reduced. Further, an electrical path between the semiconductor chip 120 and the passive components 125 may be significantly reduced, and the noise issue may thus be resolved.

Also, in the semiconductor package 100A according to the exemplary embodiment, the plurality of passive components 125 and the semiconductor chip 120 may be encapsulated separately using the first and second encapsulants 130a and 130b, and accordingly, thermal radiation properties may improve. As the amount of thermal radiation of the semiconductor chip 120 and that of the passive components 125 are different, in the case of encapsulating the semiconductor chip 120 and the passive component 125 using one encapsulant, thermal radiation may be inefficient. Particularly, properties of the passive components 125 such as an inductor and a capacitor may be affected depending on a material of an encapsulant, and accordingly, there may be degradation of electrical properties such as RF properties. However, in the fan-out semiconductor package 100A according to the exemplary embodiment, the passive components 125 and the semiconductor chip 120 may be individually encapsulated using the first and second encapsulants 130a and 130b having different levels of thermal conductivity, and accordingly, thermal radiation properties and electrical properties may be secured at the same time.

The first encapsulant 130a may have a first thermal conductivity, and the second encapsulant 130b may have a second thermal conductivity higher than the first thermal conductivity. By configuring the second encapsulant 130b encapsulating the semiconductor chip 120, an active component having a relatively high amount of thermal radiation, to have a higher thermal conductivity than that of the first encapsulant 130a encapsulating the passive components 125, thermal radiation properties of the whole semiconductor package 100A may improve. Also, by configuring the first encapsulant 130a encapsulating the passive components 125 not to include a material which may affect electrical properties, such as a metal filler, and the like, electrical properties may as well be secured. A material of the first and second encapsulants 130a and 130b may not be particularly limited. For example, an insulation material may be used, and the insulation material may be a thermosetting resin such as an epoxy resin, a thermoplastic resin such as a polyimide resin, a resin in which a reinforcing member such as a filler is included in the above resin materials, that is, for example, ABF, FR-4, BT, or the like. Also, a molding material such as an EMC may be used, and if necessary, a photosensitive material, such as a photo imageable encapsulant (PIE), may be used. Further, if necessary, a material in which an insulation resin such as a thermosetting resin or a thermoplastic resin is impregnated in an inorganic filler and/or a core material such as a glass fiber (or a glass cloth or a glass fabric) may also be used.

In the description below, elements included in the semiconductor package 100A according to an exemplary embodiment will be described in greater detail.

The core member 110 may further improve stiffness of the semiconductor package 100A depending on specific materials, and may serve to secure thicknesses uniformity of the first and second encapsulants 130a and 130b, and the like. The core member 110 may include the plurality of first and second through-holes 110Ha and 110Hb. The first and second through-holes 110Ha and 110Hb may be physically spaced apart from each other. The first through-hole 110Ha may penetrate the core member 110, and the passive components 125 may be disposed in the first through-hole 110Ha. As illustrated in FIG. 10, the passive components 125 may be spaced apart from a wall of the first through-hole 110Ha, and may be surrounded by the wall of the first through-hole 110Ha, but the present disclosure is not limited thereto. The second through-hole 110Hb may penetrate the core member 110 and the first encapsulant 130a, and the semiconductor chip 120 may be disposed in the second through-hole 110Hb. The semiconductor chip 120 may be spaced apart from a wall of the second through-hole 110Hb by a certain distance, and may be surrounded by the wall of the second through-hole 110H. However, the present disclosure is not limited to the above exemplary embodiment, but may be modified to have various forms, and depending on modified forms, different functions may be performed. If necessary, the core member 110 may be omitted, but it may be favorable to include the core member 110 to secure board level reliability intended in the present disclosure.

The core member 110 may include a core insulating layer 111, wiring layers 112 disposed on both surfaces of the core insulating layer 111, and core vias 113 penetrating the core insulating layer 111 and connecting the wiring layers 112 on upper and lower portions. Thus, the wiring layers 112 disposed on both surfaces of the core insulating layer 111 may be electrically connected to each other through the core vias 113.

As a material of the core insulating layer 111, an insulation material may be used, and in this case, the insulation material may be a thermosetting resin such as an epoxy resin, a thermoplastic resin such as a polyimide, or an insulation material in which the resin materials are impregnated in an inorganic filler and/or a core material such as a glass fiber (or a glass cloth or a glass fabric), such as prepreg, Ajinomoto Build up Film (ABF), FR-4, Bismaleimide Triazine (BT), or the like. The core member 110 may serve as a supporting member.

The wiring layers 112 may serve to redistribute the connection pads 122 of the semiconductor chip 120. A material of the wiring layers 112 may be a conductive material such as copper (Cu), aluminum (Al), silver (Ag), tin (Sn), gold (Au), nickel (Ni), lead (Pb), titanium (Ti), or alloys thereof. The wiring layers 112 may perform various functions depending on designs of corresponding layers. For example, the wiring layers 112 may include ground (GND) patterns, power (PWR) patterns, signal (S) patterns, and the like. The signal (S) patterns may include various signals except for the ground (GND) patterns, the power (PWR) patterns, and the like, such as data signals, and the like. In addition, the wiring layers 112 may include via pads, wire pads, connection terminal pads, and the like.

The core vias 113 may electrically connect the wiring layers 112 formed on different layers to each other, and form an electrical path in the core member 110 as a result. A material of the core vias 113 may also be a conductive material. Each of the core vias 113 may be completely filled with a conductive material, or the conductive material may be formed along a wall of the via hole. In addition, each of the core vias 113 may have any well-known shape such as a cylindrical shape as well as a tapered shape.

The first and second metal layers 115a and 115b may be disposed on internal walls of the first and second through-holes 110Ha and 110Hb, respectively. The first and second metal layers 115a and 115b may be disposed to surround the passive components 125 and the semiconductor chip 120, respectively, as illustrated in FIG. 10, and may be connected to at least a portion of the wiring layers 112 of the core member 110 and backside metal layers 192a and 192b of a backside wiring structure 190 in at least one area. The first and second metal layers 115a and 115b may be introduced to improve an EMI shielding effect and a thermal radiation effect of the passive components 125 and the semiconductor chip 120. The first and second metal layers 115a and 115b may include a conductive material such as copper (Cu), aluminum (Al), silver (Ag), tin (Sn), gold (Au), nickel (Ni), lead (Pb), titanium (Ti), or alloys thereof. The first and second metal layers 115a and 115b may be formed through a well-known plating process, and may be formed as a seed layer and a conductive layer. The first and second metal layers 115a and 115b may be used as a ground, and in this case, the first and second metal layers 115a and 115b may be electrically connected to a ground of the redistribution layers 142a and 142b of the connection member 140.

The semiconductor chip 120 may be an integrated circuit (IC) in which several hundreds to several millions of elements are integrated in a single chip. The semiconductor chip 120 may be a processor chip such as a central processing unit (CPU), a graphics processing unit (GPU), a field programmable gate array (FPGA), a digital signal processor, a cryptographic processor, a microprocessor, a microcontroller, or the like, or more specifically, an application processor (AP). However, the semiconductor chip 120 is not limited thereto. The semiconductor chip 120 may be a logic chip such as an analog-digital converter or an application-specific IC (ASIC) or a memory chip such as a volatile memory (e.g., DRAM) or non-volatile memory (e.g., ROM and flash memory) but is not limited thereto. These may be combined with each other as well.

In the semiconductor chip 120, a surface on which the connection pads 122 are disposed may be an active surface, and the opposite surface may be an inactive surface. The semiconductor chip 120 may be formed on the basis of an active wafer. In this case, a base material of a body 121 of the first semiconductor chip 120 may be silicon (Si), germanium (Ge), gallium arsenide (GaAs), or the like. Various circuits may be formed on the body 121. The connection pads 122 may electrically connect the first semiconductor chip 120 to other components. A material of the connection pads 122 may be a conductive material such as aluminum (Al) or the like. A passivation layer allowing the connection pads 122 to be exposed may be formed on the body 121, and the passivation layer may be an oxide layer, a nitride layer, or the like, or a double layer of an oxide layer and a nitride layer.

The each passive component 125 may be a capacitor such as a multilayer ceramic capacitor (MLCC), a low inductance chip capacitor (LICCs), an inductor such as a power inductor, or bead, and the like. The passive components 125 may have different sizes and thicknesses. In addition, the passive components 125 may have a thickness different from that of the semiconductor chip 120. The semiconductor package 100A according to the exemplary embodiment may encapsulate the passive components 125 and the semiconductor chip 120 in different processes, and accordingly, the problem of defect caused by a width difference as above may be significantly reduced. The number of the passive components 125 may not be particularly limited, and there may be a higher or lower number of the passive components 125 than in the exemplary embodiment illustrated in the diagrams.

The first encapsulant 130a may fill at least a portion of the first through-hole 110Ha, and may encapsulate at least one of the passive components 125. The encapsulating form may not be particularly limited, and various forms may be possible as long as the first encapsulant 130a embeds at least a portion of the passive components 125. The first encapsulant 130a may cover at least a portion of an upper surface of the passive components 125, and may fill at least a portion of a space between a wall of the first through-hole 110Ha and side surfaces of the plurality of passive components 125. The first encapsulant 130a may extend onto the core member 110 and disposed on the core member 110, and may be in contact with an upper surface of the core insulating layer 111.

The second encapsulant 130b may fill at least a portion of the second through-hole 110Hb, and encapsulate the semiconductor chip 120. The encapsulating form may not be particularly limited, and various forms may be possible, as long as the second through-hole 110Hb embeds at least a portion of the semiconductor chip 120. For example, the second through-hole 110Hb may cover at least a portion of the core member 110 and the inactive surface of the semiconductor chip 120, and may fill at least a portion of a space between a wall of the second through-hole 110Hb and a side surface of the semiconductor chip 120. As the second encapsulant 130b fills the second through-hole 110Hb, the second encapsulant 130b may serve as an adhesive for fixing the semiconductor chip 120 and may reduce buckling as well. As described above, the second encapsulant 130b may be disposed on an upper portion of the semiconductor chip 120, extend to upper portions of the passive components 125 and the core member 110, and be disposed on the first encapsulant 130a on the passive components 125 and the core member 110. Thus, the first and second encapsulants 130a and 130b may be sequentially layered and disposed on the passive components 125 and the core member 110, and only the second encapsulant 130b may be disposed on the semiconductor chip 120.

The first and second encapsulants 130a and 130b may include different materials, and accordingly may have different levels of thermal conductivity. As described above, the second encapsulant 130b may have a thermal conductivity higher than that of the first encapsulant 130a. Thus, a boundary between the first and second encapsulants 130a and 130b may be identified.

The connection member 140 may redistribute the connection pads 122 of the semiconductor chip 120. Through the connection member 140, several tens or several hundreds of the connection pads 122 of the semiconductor chip 120, which have a variety of functions, may be redistributed, and may be physically and/or electrically connected to external elements through the electrical connection structure 170 in accordance with the variety of functions. The connection member 140 may include a first insulating layer 141a disposed on the core member 110, the passive components 125, and the active surface of the first semiconductor chip 120, a first redistribution layer 142a disposed on the first insulating layer 141a, a first via 143a connecting the first redistribution layer 142a and the connection pads 122 of the semiconductor chip 120 and connecting the first redistribution layer 142a and the passive components 125, a second insulating layer 141b disposed on the first insulating layer 141a, a second redistribution layer 142b disposed on the second insulating layer 141b, and a second via 143b penetrating the second insulating layer 141b to connect the first and second redistribution layers 142a and 142b. The first and second redistribution layers 142a and 142b may be electrically connected to the connection pads 122 of the first semiconductor chip 120 and the passive components 125. The connection member 140 may include a larger number of the insulating layers, the redistribution layers, and the vias than in the exemplary embodiment illustrated in the diagram.

A material of each of the insulating layers 141a, 141b, and 141c may be an insulating material. In this case, a photosensitive insulating material such as a PID resin may also be used as the insulating material besides the aforementioned insulating materials. In other words, each of the insulating layers 141a and 141b may be a photosensitive insulating layer. In the case in which the insulating layers 141a and 141b have photosensitive properties, thicknesses of the insulating layers 141a and 141b may be further reduced, and a fine pitch of the vias 143a and 143b may be achieved more easily. Each of the insulating layers 141a and 141b may be a photosensitive insulating layer including an insulating resin and an inorganic filler. In the case in which the insulating layers 141a and 141b are multiple layers, materials of the insulating layers 141a and 141b may be the same, or may be different from each other if necessary. In the case in which the insulating layers 141a and 141b are the multiple layers, the insulating layers 141a and 141b may be integrated with each other depending on a process, such that a boundary therebetween may not be apparent. A larger number of insulating layers may be formed than in the exemplary embodiment in the diagram.

The redistribution layers 142a and 142b may substantially serve to redistribute the connection pads 122. A material of each of the redistribution layers 142a and 142b may be a conductive material such as copper (Cu), aluminum (Al), silver (Ag), tin (Sn), gold (Au), nickel (Ni), lead (Pb), titanium (Ti), or alloys thereof. The redistribution layers 142a and 142b may perform various functions depending on designs of respective layers. For example, the redistribution layers 142a and 142b may include ground (GND) patterns, power (PWR) patterns, signal (S) patterns, and the like. The signal (S) patterns may include various signals other than the ground (GND) patterns, the power (PWR) patterns, and the like, such as data signals, and the like. In addition, the redistribution layers 142a and 142b may include via pad patterns, electrical connection structure pad patterns, and the like.

The vias 143a and 143b may electrically connect the redistribution layers 142a and 142b, the connection pads 122, the passive components 125, and the like, formed on different layers, and form an electrical path in the package 100A as a result. A material of each of the vias 143a and 143b may be a conductive material such as copper (Cu), aluminum (Al), silver (Ag), tin (Sn), gold (Au), nickel (Ni), lead (Pb), titanium (Ti), or alloys thereof. Each of the vias 143a and 143b may be completely filled with the conductive material, or the conductive material may be formed along a wall of the vias. The vias 143a and 143b may have any well-known shape such as a tapered shape, a cylindrical shape, or the like.

The backside wiring structure 190 may include the first backside metal layer 192a disposed on the first encapsulant 130a, backside vias 193 penetrating the first and second encapsulants 130a and 130b or the second encapsulant 130b and connected to the wiring layer 112 of the core member 110 or the first backside metal layer 192a, and the second backside metal layer 192b disposed on the second encapsulant 130b and connected to the backside via 193. The first backside metal layer 192a may be connected to the first and second metal layers 115a and 115b on at least one portion. A depth of the backside via 193 in the case of being connected to the wiring layer 112 of the core member 110 and a depth of the backside via 193 in the case of being connected to the first backside metal layer 192a may be formed differently. The second backside metal layer 192b may be disposed on upper portions of the semiconductor chip 120 and the passive components 125 and improve an EMI shielding effect and a thermal radiation effect. A material of the backside metal layers 192a and 192b and the backside vias 193 may be a conductive material such as copper (Cu), aluminum (Al), silver (Ag), tin (Sn), gold (Au), nickel (Ni), lead (Pb), titanium (Ti), or alloys thereof. At least a portion of the backside metal layers 192a and 192b and the backside vias 193 may be used as a ground, and in this case, a ground on the redistribution layers 142a and 142b of the connection member 140 may be electrically connected going through the first metal layers 115a and 115b. The backside vias 193 may have a shape of a trench via or a line via extending along the semiconductor chip 120 and the passive components 125 in a direction not illustrated. In this case, the backside vias 193 may completely shield the semiconductor chip 120 and the passive component 125 along with the second backside metal layer 192b, thereby further improving an EMI shielding effect. A shape of the backside vias 193 may be a taper shape in the cross-section in the diagram, and the taper shape may be in a direction opposite to the vias 143a and 143b of the connection member 140.

The passivation layer 150 may protect the connection member 140 from external physical or chemical damage. The passivation layer 150 may have openings allowing at least a portion of the second redistribution layer 142b of the connection member 140 to be exposed. The number of openings 151 formed in the passivation layer 150 may be several tens to several thousands. A material of the passivation layer 150 may not be particularly limited. For example, an insulating material may be used as the material of the passivation layer 150. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a solder resist may also be used. The backside passivation layer 155 may also be formed on the backside wiring structure 190. The backside passivation layer 155 may protect the backside metal layers 192a and 192b. The passivation layer 150 and the backside passivation layer 155 may include the same material, and may accordingly serve to control a coefficient of thermal expansion (CTE) as a symmetrical effect.

The underbump metal layers 160 may improve connection reliability of the electrical connection structures 170, and accordingly improve board level reliability of the package 100A. The underbump metal layers 160 may be connected to the second redistribution layer 142b of the connection member 140 exposed through the openings of the passivation layer 150. The underbump metals 160 may be formed in the openings of the passivation layer 150 by any known metallization method and using any known conductive material such as a metal, but is not limited thereto.

The electrical connection structures 170 may physically and/or electrically externally connect the semiconductor package 100A. For example, the semiconductor package 100A may be mounted on the mainboard of the electronic device through the electrical connection structures 170. The electrical connection structures 170 may be formed of a conductive material, for example, a solder. However, this is only an example, and a material of the electrical connection structures 170 is not particularly limited thereto. The electrical connection structure 170 may be a land, a ball, a pin, or the like. The electrical connection structures 170 may be formed as a multilayer structure or a single layer structure. In the case in which the electrical connection structures 170 are formed as a multilayer structure, the electrical connection structures 170 may include a copper (Cu) pillar and a solder. In the case in which the electrical connection structures 170 are formed as a single layer structure, the electrical connection structures 170 may include a tin-silver solder or copper (Cu). However, this is only an example, and the electrical connection structures 170 are not limited thereto. The number, an interval, a dispositional form, and the like, of electrical connection structures 170 are not particularly limited, but may be modified in various manners in accordance with design particulars by those skilled in the art. For example, the electrical connection structures 170 may be provided in an amount of several tens to several thousands, or more than several tens to several thousands or less than tens to several thousands.

At least one of the electrical connection structures 170 may be disposed in a fan-out region of the semiconductor chip 120. The fan-out region may refer to a region beyond a region in which the semiconductor chip 120 is disposed. The fan-out package may have excellent reliability as compared to a fan-in package, may implement a plurality of input/output (I/O) terminals, and may facilitate a 3D interconnection. In addition, as compared to a ball grid array (BGA) package, a land grid array (LGA) package, or the like, the fan-out package may be manufactured to have a reduced thickness, and may have price competitiveness.

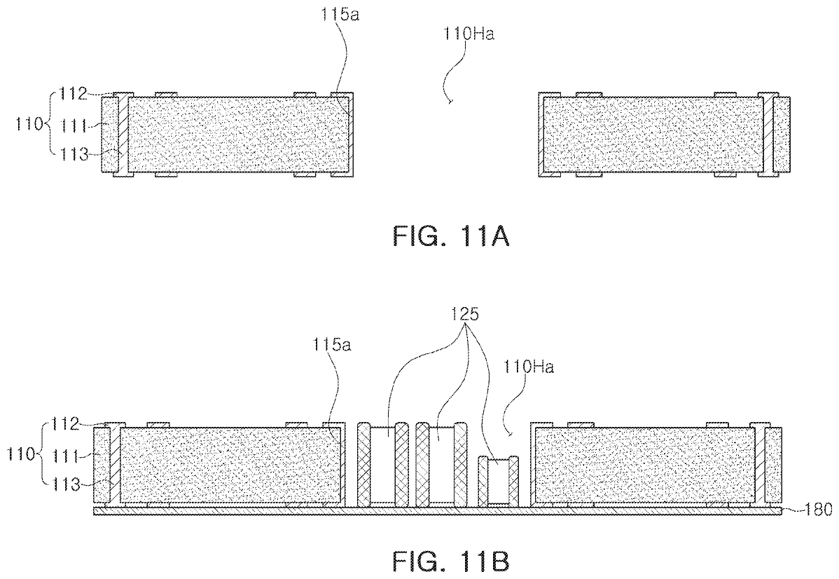

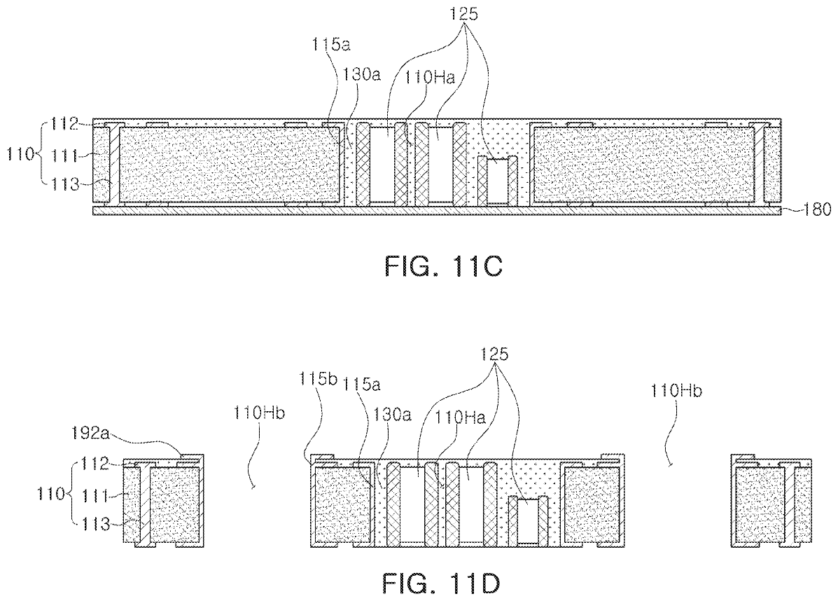

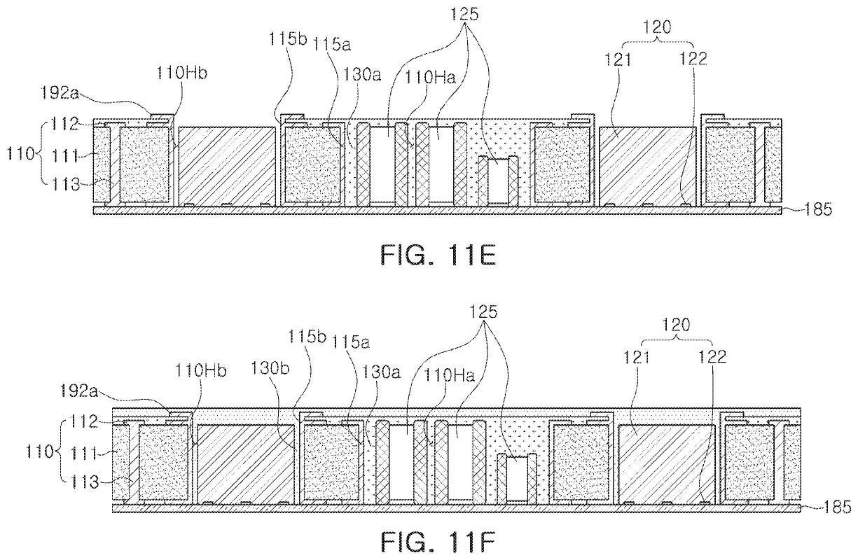

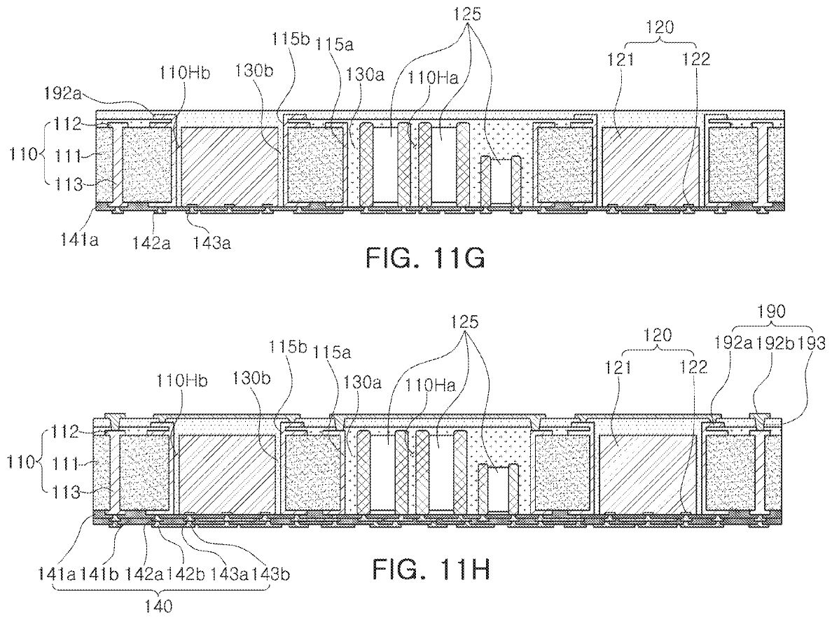

FIGS. 11A to 11I are views illustrating an exemplary embodiment of processes of manufacturing a semiconductor package in FIG. 9.

Referring to 11A, a core member 110 may be prepared, a first through-hole 110Ha penetrating upper and lower surfaces of the core member 110 may be formed, and a first metal layer 115a may be formed on an internal wall of the first through-hole 110Ha. The first through-hole 110Ha may be formed using mechanical drilling and/or laser drilling. However, the present disclosure is not limited thereto. The first through-hole 110Ha may be formed by a sand blast method using particles for polishing, a dry etching method using plasma, or the like, depending on a material of a core insulating layer 111. A size, a shape, and the like, of the first through-hole 110Ha may be designed in accordance with a size, a shape, a number, and the like of passive components 125 to be mounted. The first metal layer 115a may be formed by a plating process, and may also be formed along with wiring layers 112 and a core via 113 of the core member 110. The first metal layer 115a may be connected to the wiring layers 112 on upper and lower surfaces of the core member 110. It may be interpreted that a portion of the wiring layers 112 forms the first metal layer 115a, and in this case, the first metal layer 115a may specifically refer to a region disposed in an internal wall of the first through-hole 110Ha in the wiring layer 112.

Referring to FIG. 11B, an adhesive film 180 may be attached to a portion of the core member 110, and the passive components 125 may be disposed in the first through-hole 110Ha. A type of the adhesive film 180 is not particularly limited as long as the adhesive film 180 is able to fix the core member 110. For example, a well-known tape may be used as the adhesive film 180. An example of the well-known tape may be a thermal treatment curable adhesive tape of which adhesive strength weakens by thermal treatment, an ultraviolet curable adhesive tape of which adhesive strength weakens by ultraviolet radiation, and the like. The passive component 125 may be disposed by attaching the passive component 125 to a surface of the adhesive film 180 in the first through-hole 110Ha, for example.

Referring to FIG. 11C, the passive components 125 may be sealed using the first encapsulant 130a, and the adhesive film 180 may be stripped. The first encapsulant 130a may seal at least an upper surface of the core member 110 and the passive components 125, and may fill a space in the first through-hole 110Ha. The first encapsulant 130a may be formed by a well-known method. For example, the first encapsulant 130a may be formed by laminating and curing a precursor of the first encapsulant 130a, or may be formed by coating a surface of the adhesive film 180 with the first encapsulant 130a to seal the passive components 125 and being cured. By the curing, the passive components 125 may be fixed. As the laminating method, for example, a method in which a hot press process where a pressure is applied to an object in high temperature for a certain period of time and is reduced, the object is cooled in a cold press, and a working tool is separated, or the like, may be used. As the coating method, for example, a screen printing method of applying ink using a squeegee, a spray printing method of atomizing ink and spraying the atomized ink, or the like, may be used. The method of stripping the adhesive film 180 may not be particularly limited, but may be implemented by a well-known method. For example, in the case in which a thermal treatment curable adhesive tape of which adhesive strength weakens by thermal treatment, an ultraviolet curable adhesive tape of which adhesive strength weakens by ultraviolet radiation, or the like is used, the stripping of the adhesive film 180 may be formed after weakening an adhesive strength thereof by thermal treatment of the adhesive film 180, or by radiating ultraviolet rays to the adhesive film 180.

Referring to FIG. 11D, a second through-hole 110Hb penetrating upper and lower surfaces of the core member 110 and the first encapsulant 130a may be formed, a second metal layer 115b may be formed in an internal wall of the second through-hole 110Hb, and a first backside metal layer 192a may be formed on the first encapsulant 130a. The second through-hole 110Hb may be formed by mechanical drilling and/or laser drilling. The second through-hole 110Hb may be formed to be spaced apart from the first through-hole 110Ha, and a size, a shape, and the like, of the second through-hole 110Hb may be designed in accordance with a size, a shape, and the number of the semiconductor chip 120 to be mounted. The second metal layer 115b may be formed by a plating process, and may be connected to the wiring layer 112 on upper and/or lower surfaces of the core member 110. In the plating process, a plating material may extend from the second metal layer 115b to the first encapsulant 130a, and may form a first backside metal layer 192a.

Referring to FIG. 11E, an adhesive film 185 may be attached to a portion of the core member 110, and the semiconductor chip 120 may be disposed in the second through-hole 110Hb. The semiconductor chip 120 may be disposed, for example, by attaching the semiconductor chip 120 to a surface of the adhesive film 185 in the second through-hole 110Hb. The semiconductor chip 120 may be disposed in face-down form such that connection pads 122 are attached to the adhesive film 185.

Referring to FIG. 11F, the semiconductor chip 120 may be encapsulated using the second encapsulant 130b, and the adhesive film 185 may be stripped. The second encapsulant 130b may encapsulate the core member 110 and at least an inactive surface of the semiconductor chip 120, and fill a space in the second through-hole 110Hb. The second encapsulant 130b may be formed to cover the first encapsulant 130a on the core member 110 and the passive components 125. As for the process of forming the second encapsulant 130b and the process of stripping the adhesive film 185, the aforementioned same descriptions of the process of forming the first encapsulant 130a and the process of stripping the adhesive film 180 described with reference to FIG. 11C may be applied to the processes.

Referring to FIG. 11G, a first insulating layer 141a, a first redistribution layer 142a, and a first via 143a of the connection member 140 may be formed on the core member 110 on which the adhesive film 185 is removed, an active surface of the semiconductor chip 120, and an lower surface of the passive components 125. The first insulating layer 141a may be formed by laminating a photoimageable dielectrics (PID) insulating material, forming a via hole using a photo via, and forming the first redistribution layer 142a and the first via 143a by a plating process.

Referring to FIG. 11H, a second insulating layer 141b, a second via 143b, and a second redistribution layer 142b of a connection member 140 may be formed, and a backside via 193 penetrating the first and second encapsulants 130a and 130b and a second backside metal layer 192b may be formed on the second encapsulant 130b. Accordingly, the connection member 140 and a backside wiring structure 190 may be ultimately formed. In accordance with the exemplary embodiments, the connection member 140 may be formed, and then the backside via 193 and the second backside metal layer 192b of the backside wiring structure 190 may be formed, or the second via 143b and the second redistribution layer 142b may be simultaneously formed with the backside via 193 and the second backside metal layer 192b.

Referring to FIG. 11I, a passivation layer 150 covering the second redistribution layer 142b may be formed, openings allowing at least a portion of the second redistribution layer 142b to be exposed may be formed on the passivation layer 150, and an underbump metal layer 160 may be formed on the openings. Also, a backside passivation layer 155 may be formed on the second encapsulant 130b and the backside wiring structure 190. The passivation layer 150 may be formed by laminating and curing a precursor of the passivation layer 150, by spraying and curing a material of the passivation layer 150, or the like. The backside passivation layer 155 may be formed by the same method as above, and may be formed simultaneously with the passivation layer 150, or formed by a separate process. The underbump metal layer 160 may be formed by a well-known metalizing method.

Also, referring to the diagram along with FIG. 9, the electrical connection structure 170 may be formed on the underbump metal layer 160. A method of forming the electrical connection structure 170 may not be particularly limited, but may be formed by a well-known method in the respective technical field depending on a structure or a shape. The electrical connection structure 170 may be fixed by reflow, and to enhance fixing strength, a portion of the electrical connection structure 170 may be embedded in the passivation layer 150, and a remaining portion may be exposed externally, thereby improving reliability. In some cases, only up to the process of forming the underbump metal layer 160 may be performed, and the subsequent processes may be performed as separate processes if necessary.

Meanwhile, a series of processes may include, after preparing the core member 110 of a high capacity size and manufacturing a plurality of packages 100A through the aforementioned processes, a process of singulation as a separate package 100A through a sawing process.

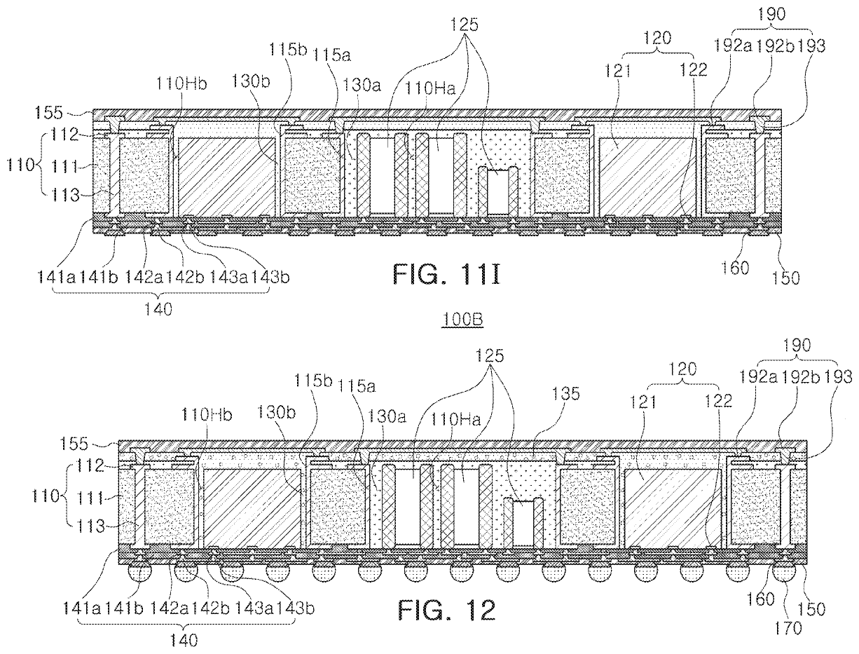

FIG. 12 is a cross-sectional view of another exemplary embodiment of a semiconductor package.

Referring to FIG. 12, in a semiconductor package 100B according to another exemplary embodiment, a second encapsulant 130b may further include a thermal conductive filler 135. For example, a first encapsulant 130a and the second encapsulant 130b may use the same or similar type of resin insulating material, and the second encapsulant 130b may further include the thermal conductive filler 135, and accordingly, the second encapsulant 130b may have thermal conductivity higher than that of the first encapsulant 130a. For example, even in the case in which the thermal conductive filler 135 includes a conductive material, passive components 125 including high frequency passive components affected by electrical properties depending on an encapsulating material may be encapsulated by the first encapsulant 130a which does not include the thermal conductive filler 135 as above, and thus, degradation of electrical properties may not occur.

The thermal conductive filler 135 may include at least one of a carbon filler, a metal filler, a metal compound filler, a resin filler, and an inorganic filler. The carbon filler may include at least one of carbon nanotubes, graphene, graphene oxide, graphite, carbon black, and a carbon-metal compound. The metal filler may include at least one of a metal particle of nickel (Ni), zinc (Zn), magnesium (Mg), silver (Ag), and copper (Cu). The inorganic filler may include at least one of aluminum nitride, alumina, boron nitride, silica, silicon carbide, magnesium oxide, zinc oxide, and titanium. The descriptions for the other components or manufacturing methods will not be repeated as they are substantively the same as in the description of the semiconductor package 100A.

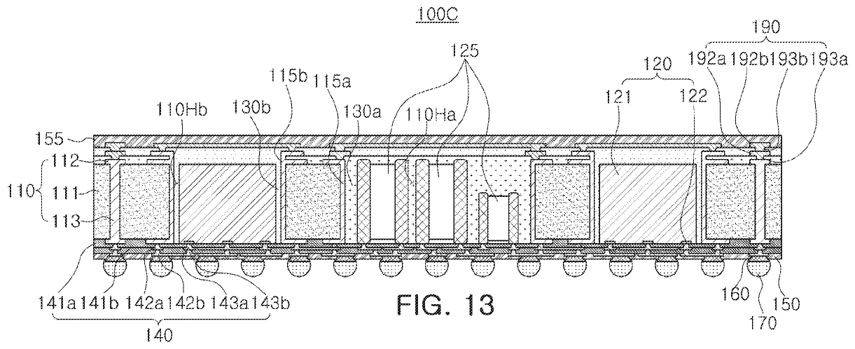

FIG. 13 is a cross-sectional view illustrating another exemplary embodiment of a semiconductor package.

Referring to FIG. 13, in a semiconductor package 100C according to another exemplary embodiment, a backside wiring structure 190 may include first and second backside metal layers 192a and 192b and first and second backside vias 193a and 193b. In other words, the semiconductor package 100C may further include the first backside via 193a penetrating at least a portion of a first encapsulant 130a and connecting a wiring layer 112 of the core member 110 and the first backside metal layer 192a in addition to the second backside via 193b connected to the second backside metal layer 192b. The first backside via 193a may be formed before the first backside metal layer 192a is formed. A material of the first and second backside vias 193a and 193b may be a conductive material such as copper (Cu), aluminum (Al), silver (Ag), tin (Sn), gold (Au), nickel (Ni), lead (Pb), titanium (Ti), or alloys thereof. The descriptions for the other components or manufacturing methods will not be repeated as they are substantively the same as in the description of the semiconductor package 100A.

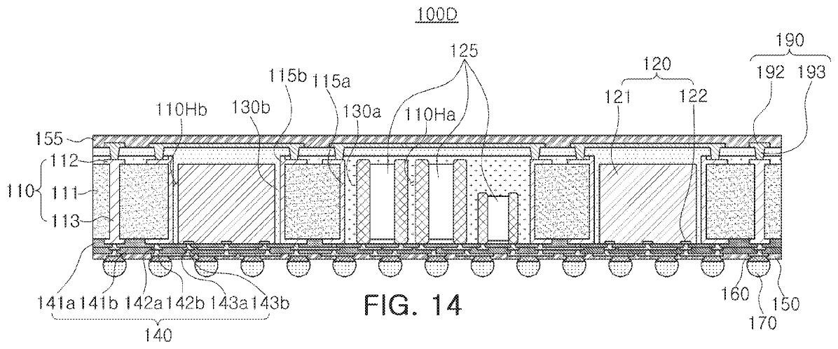

FIG. 14 is a cross-sectional view illustrating another exemplary embodiment of a semiconductor package.

Referring to FIG. 14, in a semiconductor package 100D according to another exemplary embodiment, a backside wiring structure 190 may include a backside metal layer 192 and a backside via 193. In other words, the semiconductor package 100D may include the backside metal layer 192 on a second encapsulant 130b and the backside via 193 penetrating a first encapsulant 130a and the second encapsulant 130b and connecting the backside metal layer 192 and the wiring layer 112 of the core member 110. The backside via 193 may be a line via or a trench via extending along a semiconductor chip 120 and passive components 125 in a direction not illustrated. The descriptions for the other components or manufacturing methods will not be repeated as they are substantively the same as in the description of the semiconductor package 100A.

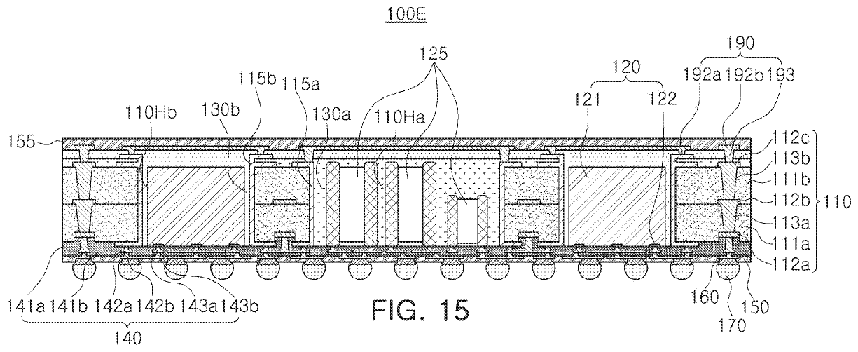

FIG. 15 is a cross-sectional view illustrating another exemplary embodiment of a semiconductor package.

Referring to FIG. 15, in a semiconductor package 100E according to another exemplary embodiment, a core member 110 may include a first core insulating layer 111a contacting a connection member 140, a first wiring layer 112a contacting the connection member 140 and embedded in the first core insulating layer 111a, a second wiring layer 112b disposed to oppose an area in which the first wiring layer 112a of the first core insulating layer 111a is embedded, a second insulating layer 111b disposed on the first core insulating layer 111a and covering the second wiring layer 112b, and a third wiring layer 112c disposed on the second insulating layer 111b. The first to third wiring layers 112a, 112b, and 112c may be electrically connected to connection pads 122. The first and second wiring layers 112a and 112b, and the second and third wiring layers 112b and 112c may be electrically connected to each other through first and second core vias 113a and 113B penetrating the first and second insulating layers 111a and 111b, respectively.

The first wiring layer 112a may be recessed internally of the first core insulating layer 111a. In the case in which the first wiring layer 112a is recessed internally of the first core insulating layer 111a as above, so that a lower surface of the first core insulating layer 111a and a lower surface of the first wiring layer 112a have stepped portions, pollution of the first wiring layer 112a caused by bleeding of the material of the first encapsulant 130 may be prevented. Thicknesses of the wiring layers 112a, 112b, and 112c of the core member 110 may be greater than those of redistribution layers 142a, 142b, and 142c of the connection member 140.

When a hole for the first core via 113a is formed, some of pads of the first wiring layer 112a may serve as a stopper. Thus, it may be favorable to configure the first core via 113a to have a tapered shape in which a width of an upper surface of the first core via 113a is greater than that of a lower surface in terms of process. In this case, the first core via 113a may be integrated with a pad pattern of the second wiring layer 112b. Also, when a hole for the second core via 113b is formed, some of pads of the second wiring layer 112b may serve as a stopper, and thus, it may also be favorable to configure the second core via 113b to have a tapered shape in which a width of an upper surface of the second core via 113b is greater than that of a lower surface in terms of process. In this case, the second core via 113b may be integrated with a pad pattern of the third wiring layer 112c.

The descriptions of the other components, such as the first and second encapsulants 130a and 130b, and the like, described with reference to FIG. 9 and others, may be applied to the semiconductor package 100E according to another exemplary embodiment. Thus, the detailed descriptions of the components will not be repeated as the descriptions are substantively the same as in the description of the semiconductor package 100A above.

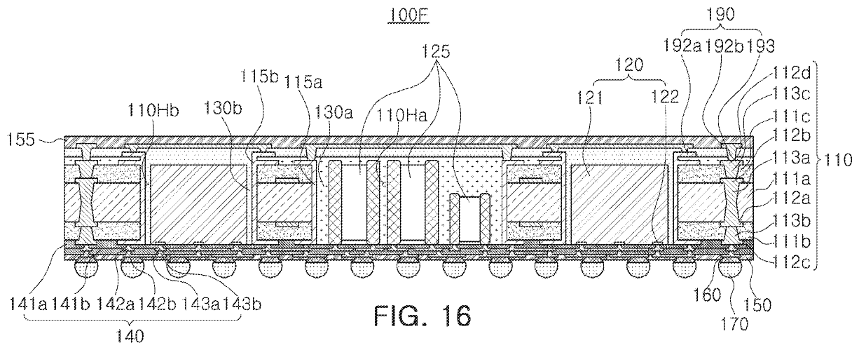

FIG. 16 is a cross-sectional view illustrating another exemplary embodiment of a semiconductor package.

Referring to FIG. 16, in a semiconductor package 100F, a core member 110 may include a first core insulating layer 111a, a first wiring layer 112a and the second wiring layer 112b disposed on both surfaces of the first core insulating layer 111a, a second insulating layer 111b disposed on the first insulating layer 112a and covering the first wiring layer 112a, a third redistribution layer 112c disposed on the second insulating layer 111b, a third insulating layer 111c disposed on the first core insulating layer 111a and covering the second wiring layer 112b, and a fourth wiring layer 112d disposed on the third insulating layer 111c. The first to fourth wiring layers 112a, 112b, 112c, and 112d may be electrically connected to connection pads 122. As the core member 110 include a larger number of wiring layers 112a, 112b, 112c, and 112d, a connection member 140 may be further simplified. Accordingly, yield degradation caused by defects occurring in the process of forming the connection member 140 may be resolved. Meanwhile, the first to fourth wiring layers 112a, 112b, 112c and 112d may be electrically connected through the first to third core vias 113a, 113b, and 113c penetrating the first to third core insulating layers 111a, 111b, and 111c, respectively.

A thickness of the first core insulating layer 111a may be greater than those of the second and third insulating layers 111b and 111c. Basically, the first core insulating layer 111a may have a relatively large thickness to maintain stiffness, and the second and third core insulating layers 111b and 111c may be introduced to form a larger number of wiring layers 112c and 112d. The first core insulating layer 111a may include an insulating material different from those of the second and third core insulating layers 111b and 111c. For example, the first core insulating layer 111a may be, for example, a prepreg including a core, a filler, and an insulating resin, and the second and third core insulating layers 111b and 111c may be an ABF film or a PID film including a filler and an insulating resin, but are not limited thereto. Similarly, the first core via 113a penetrating the first core insulating layer 111a may have a diameter greater than those of the second and third core vias 113b and 113C penetrating the second and third core insulating layers 111b and 111c. Thicknesses of the wiring layers 112a, 112b, 112c, and 112d of the core member 110 may be greater than those of redistribution layers 142a, 142b, and 142c of the connection member 140.

The descriptions of the other components, such as the first and second encapsulants 130a and 130b, and the like, described with reference to FIG. 9 and others, may be applied to the semiconductor package 100E according to another exemplary embodiment. Thus, the detailed descriptions of the components will not be repeated as the descriptions are substantively the same as in the description of the semiconductor package 100A above.

In the present disclosure, the terms “lower portion,” “lower surface,” and the like, may imply a direction towards amounting surface of a fan-out semiconductor package, and the terms “upper portion,” “upper surface,” and the like, may indicate the opposite direction. However, the directions are defined as above for ease of description, and the scope of present disclosure is not particularly limited thereto.

In the present disclosure, the term “connected,” or “connecting” may include the case in which components are indirectly connected through an adhesive layer, or the like. Also, “electrically connected,” or “electrically connecting” may include the case in which components are physically connected and the case in which components are not physically connected. In addition, the terms “first,” and “second” are used to distinguish one component from another, and do not delimit an order and/or importance, and the like, of the components. In some cases, a first component may be referred to as a second component without departing from the scope of rights of the present disclosure, and likewise a second component may be referred to as a first component.

As one of the effects of the present disclosure, a semiconductor package having improved thermal radiation properties may be provided.

The term “exemplary embodiment” may not necessarily indicate one same exemplary embodiment, but may be provided to emphasize different unique features of the present disclosure. However, it may not necessarily exclude a combination of the suggested exemplary embodiments with another exemplary embodiment. For example, although a description of a certain component in one exemplary embodiment is not provided in another exemplary embodiment, it is to be understood that the description may relate to the other exemplary embodiment unless otherwise indicated in the other exemplary embodiment.

The terms used in the present disclosure are used to describe exemplary embodiments, and are not intended to be limiting. A singular term includes a plural form unless otherwise indicated.

While the exemplary embodiments have been shown and described above, it will be apparent to those skilled in the art that modifications and variations could be made without departing from the scope of the present invention as defined by the appended claims.

What is claimed is:

1. A semiconductor package, comprising:
a core member having first and second through-holes;
a passive component disposed in the first through-hole of the core member;
a semiconductor chip disposed in the second through-hole of the core member and having an active surface on which connection pads are disposed and an inactive surface opposing the active surface;
a first encapsulant encapsulating at least a portion of the passive component and having a first thermal conductivity;
a second encapsulant encapsulating at least a portion of the semiconductor chip and having a second thermal conductivity higher than the first thermal conductivity; and
a connection member disposed on the active surface of the semiconductor chip and including a redistribution layer electrically connected to the connection pads of the semiconductor chip.

2. The semiconductor package of claim 1, wherein the second encapsulant further comprises a thermal conductive filler.

3. The semiconductor package of claim 2, wherein the thermal conductive filler comprises at least one of a carbon filler, a metal filler, a metal compound filler, a resin filler, and an inorganic filler.

4. The semiconductor package of claim 1, wherein the first and second encapsulants are sequentially disposed on the core member.

5. The semiconductor package of claim 1, wherein the second encapsulant extends to an upper portion of the passive component and disposed on the first encapsulant.

6. The semiconductor package of claim 1, further comprising:
a backside via penetrating through the first and second encapsulants and connected to a wiring layer of the core member; and
a backside metal layer disposed on the backside via.

7. The semiconductor package of claim 6, where the backside metal layer covers the passive component and the semiconductor chip.

8. The semiconductor package of claim 6, wherein the backside via has a linear shape extending in one direction.

9. The semiconductor package of claim 1, further comprising:
a first backside metal layer disposed on the first encapsulant and a second backside metal layer disposed on the second encapsulant.

10. The semiconductor package of claim 9, wherein the second backside metal layer covers the passive component and the semiconductor chip.

11. The semiconductor package of claim 1, further comprising:
a metal layer disposed along internal walls of the first and second through-holes.

12. The semiconductor package of claim 1, wherein the second through-hole penetrates through the core member and the first encapsulant.

13. The semiconductor package of claim 1, wherein the core member comprises a first core insulating layer, a first wiring layer contacting the connection member and embedded in the first core insulating layer, and a second wiring layer opposing a portion of the first core insulating layer in which the first wiring layer is embedded, and the first and second wiring layers are electrically connected to the connection pads.

14. The semiconductor package of claim 13, wherein the core member further comprises a second core insulating layer disposed on the first core insulating layer and covering the second wiring layer, and a third wiring layer disposed on the second core insulating layer, and the third wiring layer is electrically connected to the connection pads.

15. The semiconductor package of claim 1, wherein the core member further comprises the first core insulating layer, and a first wiring layer and a second wiring layer disposed on both surfaces of the first core insulating layer, and the first and second wiring layers are electrically connected to the connection pads.

16. The semiconductor package of claim 15, wherein the core member further comprises the second core insulating layer disposed on the first core insulating layer and covering the first wiring layer, and the third wiring layer disposed on the second core insulating layer, and the third wiring layer is electrically connected to the connection pads.

17. The semiconductor package of claim 1, wherein the redistribution layer of the connection member is electrically connected to the passive component.

18. The semiconductor package of claim 1, further comprising:
a backside metal layer disposed on the second encapsulant and covering the passive component and the semiconductor chip;
a metal layer disposed on internal walls of the first and second through-holes; and
backside vias penetrating through one or more of the first and second encapsulants and connecting the metal layer and the backside metal layer to each other.

19. A semiconductor package, comprising:
a semiconductor chip having an active surface on which connection pads are disposed and an inactive surface opposing the active surface;
a passive component disposed in parallel to the semiconductor chip;
a first encapsulant encapsulating at least a portion of the passive component and having a first thermal conductivity;
a second encapsulant encapsulating at least a portion of the semiconductor chip and having a second thermal conductivity higher than the first thermal conductivity; and
a connection member disposed on the active surface of the semiconductor chip and including a redistribution layer electrically connected to the connection pads of the semiconductor chip.

20. The semiconductor package of claim 19, wherein the second encapsulant extends to an upper portion of the first encapsulant.
